(19) United States
(12) Patent Application Publication
(10) Pub. No.: US 2025/0309859 A1
(43) Pub. Date: Oct. 2, 2025

(54) DUAL-MODE MEMS RESONATORS WITH LOW SUPPORT LOSS

(71) Applicant: Panasonic Corporation of North America, Newark, NJ (US)

(72) Inventors: Amir Maymandi Rahafrooz, Waltham, MA (US); Ijaz Jafri, Waltham, MA (US)

(21) Appl. No.: 19/091,042

(22) Filed: Mar. 26, 2025

Related U.S. Application Data
(60) Provisional application No. 63/571,501, filed on Mar. 29, 2024.

(51) Int. Cl. H03H 9/02; H03H 9/24

(52) U.S. Cl. CPC H03H 9/02259; H03H 9/02338; H03H 9/2447; H03H 2009/02251; H03H 2009/02291; H03H 2009/02503

(57) ABSTRACT

A dual-mode resonator assembly includes a plurality of electrodes disposed around the resonator and configured to transduce information related to a first mode of operation of the dual-mode resonator assembly and a second mode of operation of the dual-mode resonator assembly. The plurality of electrodes includes electrodes associated with the first mode of operation and electrodes associated with the second mode of operation. The plurality of electrodes are disposed symmetrically and centered to nodes and antinodes of the first mode of operation and/or the second mode of operation. The electrodes are configured to also minimize feedback and noise from the first and second mode of operation.

### CROSS REFERENCE TO RELATED APPLICATIONS

This application claims priority to U.S. Provisional Application Ser. No. 63/571,501, filed on Mar. 29, 2024, titled “DUAL-MODE MEMS RESONATORS WITH LOW SUPPORT LOSS,” the entirety of which is incorporated herein by reference.

### BACKGROUND

Precision timing can be crucial in various electronic applications. Silicon Micro-Electro-Mechanical systems (MEMS) oscillators are favored for timing applications due to their cost-effectiveness, compact size, low power consumption, and shock resistance. To enhance temperature stability, two resonance modes with different temperature coefficients of frequency (TCF) are typically employed-one with low TCF for the timing reference and another with a larger TCF as a temperature sensor for compensating remaining temperature variations. Traditionally, these resonance modes belong to separate resonators, leading to hysteresis and a larger footprint.

### BRIEF SUMMARY

According to an embodiment described herein, a dual-mode resonator comprising a resonator assembly comprising a plurality of proof-masses configured to vibrate in a first mode of operation and a second mode of operation. The dual-mode resonator assembly comprises at least one anchor, at least one beam, and a decoupling structure. The plurality of proof-masses being coupled to the at least one anchor by the at least one beam and the decoupling structure and a plurality of electrodes disposed around the periphery of the resonator assembly and configured to transduce information related to the first mode of operation and the second mode of operation. The plurality of electrodes comprising at least two sets of first electrodes configured to operate the first mode of operation, and at least two sets of second electrodes configured to operate the second mode of operation. The operation of the dual-mode resonator in the first mode of operation results in minimal vibration or movement at a plurality of first nodes and maximum vibration or movement at a plurality of first antinodes, and the operation of the dual-mode resonator in the second mode of operation results in minimum vibration at a plurality of second nodes and maximum vibration or movement at a plurality of second antinodes.

A dual-mode according to an aspect of the present disclosure includes the first mode of operation is a low temperature coefficient of frequency (TCF) mode configured to create a reference clock signal and the second mode of operation is a high TCF mode configured to sense temperature and perform temperature compensation.

A dual-mode according to an aspect of the present disclosure includes at least two sets of first electrodes are configured to only operate the first mode of operation, and at least two sets of second electrodes are configured to only operate the second mode of operation.

A dual-mode according to an aspect of the present disclosure includes at least two sets of first electrodes are disposed symmetrically around the plurality of first nodes.

A dual-mode according to an aspect of the present disclosure includes at least two sets of second electrodes are disposed symmetrically around the plurality of first nodes.

A dual-mode according to an aspect of the present disclosure includes at least two sets of first electrodes and the at least two sets of second electrodes are disposed symmetrically around the plurality of first nodes.

A dual-mode according to an aspect of the present disclosure includes at least two sets of first electrodes are disposed symmetrically around the plurality of first antinodes.

A dual-mode according to an aspect of the present disclosure includes at least two sets of second electrodes are disposed symmetrically around the plurality of first antinodes.

A dual-mode according to an aspect of the present disclosure includes at least two sets of first electrodes and the at least two sets of second electrodes are disposed symmetrically around the plurality of first antinodes.

A dual-mode according to an aspect of the present disclosure includes at least two proof-masses of the plurality of proof-masses are coupled together by at least two beams.

A dual-mode according to an aspect of the present disclosure includes at least two sets of proof-masses of the plurality of proof-masses are coupled together by at least two beams, wherein each set of proof-masses comprise two proof-masses connected together by a single beam.

A dual-mode according to an aspect of the present disclosure includes at least four proof-masses of the plurality of proof-masses are coupled together by at least four beams.

A dual-mode according to an aspect of the present disclosure includes a first mode of operation is a Lamé mode.

A dual-mode according to an aspect of the present disclosure includes a first mode of operation is a wineglass mode.

A dual-mode according to an aspect of the present disclosure includes a second mode of operation is an extensional mode.

A dual-mode according to an aspect of the present disclosure includes a second mode of operation is a breathing mode.

A dual-mode according to an aspect of the present disclosure includes at least two sets of first electrodes comprise two sets of first differential electrodes, and the at least two sets of second electrodes comprise two sets of second differential electrodes.

A dual-mode according to an aspect of the present disclosure includes at least two sets of first electrodes comprise at least one set of electrodes that is not a differential electrode set.

### BRIEF DESCRIPTION OF THE DRAWINGS

Various aspects of at least one example are discussed below with reference to the accompanying figures, which are not intended to be drawn to scale. The figures are included to provide an illustration and a further understanding of the various aspects and are incorporated in and constitute a part of this specification but are not intended as a definition of the limits of any particular example. The drawings, together with the remainder of the specification, serve to explain principles and operations of the described and claimed aspects. In the figures, each identical or nearly identical component that is illustrated in various figures is represented by a like numeral.

FIGS. 1 and 2 illustrate an example architecture for resonator structures, in accordance with at least one embodiment as described herein.

FIG. 3 illustrates views of resonators in various operational modes, in accordance with at least one embodiment as described herein.

FIG. 4A-4B illustrate a general proposed modal interaction diagram, in accordance with at least one embodiment as described herein.

FIGS. 5A-5E illustrate a first resonator embodiment, in accordance with at least one embodiment as described herein.

FIGS. 6A-6H illustrate a second resonator embodiment, in accordance with at least one embodiment as described herein.

FIGS. 7A-7H illustrate a third resonator embodiment, in accordance with at least one embodiment as described herein.

FIGS. 8A-8G illustrate a fourth resonator embodiment, in accordance with at least one embodiment as described herein.

FIGS. 9A-9G illustrate a fifth resonator embodiment, in accordance with at least one embodiment as described herein.

### DETAILED DESCRIPTION

While the present disclosure is generally directed to MEMS oscillators in timing devices, one in the art would understand that the teachings herein can also be applied to energy harvesters, gyroscopes, accelerometers, transducers, and other MEMS applications

Support loss in resonators can directly impact performance. Improving support loss becomes more challenging for smaller dimensional resonators. In the case of temperature-stable MEMS, usually two resonance modes are needed. The first mode includes a lower TCF used to create a reference clock. A second mode includes higher TCF and is used to sense temperature and perform temperature compensation as needed. If the two resonance modes belong to the same small resonator body (as described hereinbelow), such a design creates various benefits and challenges. The benefits include a smaller footprint and better temperature sensing (e.g., sensing the temperature at the right location) leading to less hysteresis and variation. The challenges include maintaining low support loss for both modes at the same time and potential degraded performance due to modal interaction (e.g., via mechanical and/or electrical interaction).

The present disclosure overcomes the drawbacks of prior art MEMS resonators. In particular, using compact dual-mode resonators that share the same resonator body can address challenges related to low support loss for both low TCF mode (for timing reference) and higher TCF mode (for compensating for remaining temperature variations). The dual-mode resonator assemblies as described herein also address challenges related to mitigating modal interactions, thereby improving overall performance.

More specifically, using compact dual-mode resonator assemblies that utilize a shared resonator body leads to reduced hysteresis and a smaller footprint. Using the mechanisms of this disclosure can provide very low support-loss for both modes simultaneously. Additionally, by strategically positioning electrodes around the resonator, it becomes possible to selectively target one mode for transduction without affecting the other mode. This feature helps minimize or eliminate modal interaction between the two modes, thereby enhancing overall performance.

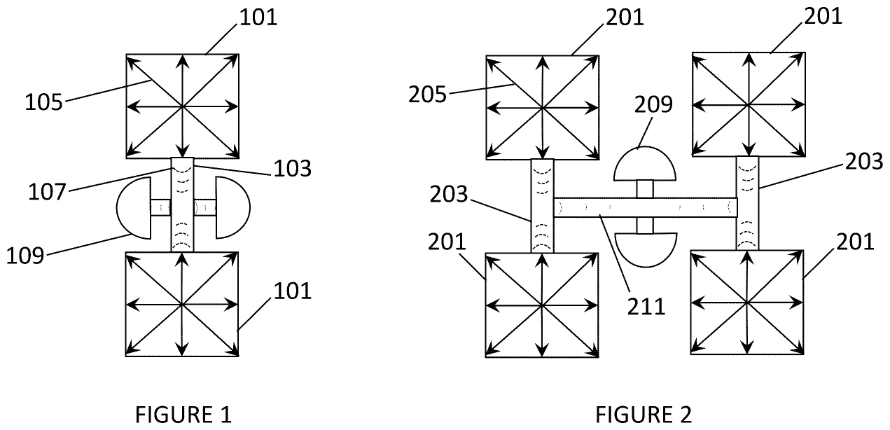

Resonators and mode-shapes can be designed such that the structures intrinsically have low support loss. For example, referring to FIG. 1, two identical proof-masses 101 are connected using a connecting beam 103. The two proof-masses 101 can vibrate at specific frequencies in specific manners. Here, as convenience, these vibrations are shown using arrows 105. Resonators can exhibit standing wave patterns when vibrating or oscillating. Standing wave patterns can be characterized by alternating nodes and antinodes. Nodes can represent points of minimal vibration or movement, while antinodes can represent points of maximum vibration or movement. Nodes typically occur at fixed ends where movement is constrained and antinodes typically occur at open ends where movement is not constrained.

The vibrating proof-masses 101 can cause displacements 107 in the beam 103. For example, the displacements caused by each proof-mass 101 in the beam 103 can be in opposite directions, canceling each other out, and create an ideal location for an anchor 109. The anchor 109 can be the point or structure where the resonator is physically fixed or attached to a substrate or other medium. The anchor 109 can be used as an electrode. Here, the resonator design of FIG. 1 has two anchors 109, attached at the center point of the beam 103. This attachment point can be different, for example the attachment point can be moved closer to one proof-mass 101 based on desired frequency stability and/or design parameters.

In certain implementations, the structure of FIG. 1 can be multiplied and connected in parallel based on desired parameters and use, as illustrated in FIG. 2. For example, two structures illustrated in FIG. 1 can be connected together. The resulting structure can have two sets of two proof-masses 201 with parallel beams 203 connected together using center beam 211. Because the structures are parallel and the anchors are connected through a center beam 211, the nodes of the beams can provide much lower support loss than the design in FIG. 1.

It should be noted that while arrows 105 and arrows 205 depict many possible directions of vibration, these directions are used for convenience. The vibrations can be in one direction, opposite directions for each proof-mass, and different. The design of the structures in FIGS. 1 and 2, can be modified for different resonance modes, as well as different shapes for proof-masses (e.g., square, disk, rectangle, etc.). For example, electrodes can be placed at nodes or antinodes of one mode to ensure exciting and picking off only a specific resonance mode.

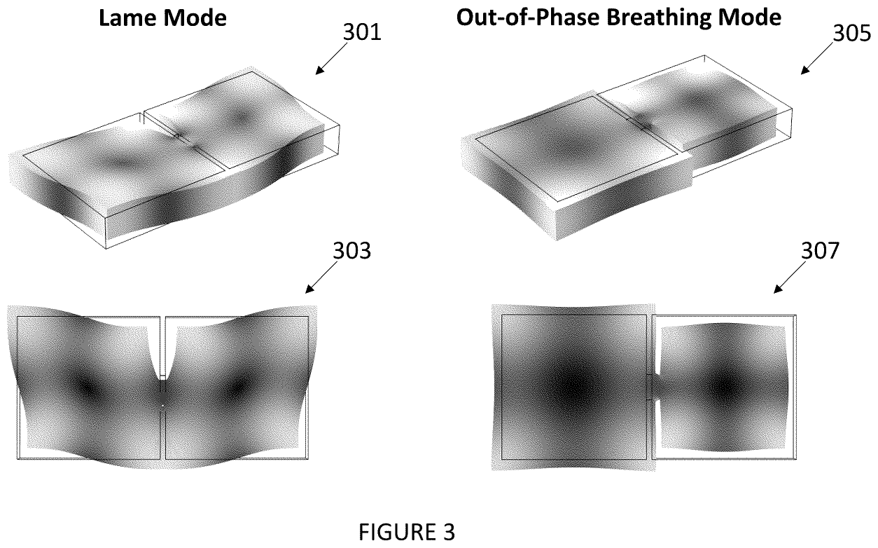

For differential excitation and differential readout, this design can potentially provide two advantages. First, in cases that single-ended excitation or drive can transduce the unwanted mode, having two differential electrodes can still ensure transducing only the target mode. Second, there can be significant feedthrough between excitation and pick-off electrodes. But using differential electrodes significantly reduces feedthrough and improves signal-to-noise ratio (SNR). For example, referring to FIG. 3, two coupled square proof-masses are illustrated in Lamé mode and out-of-phase breathing modes. FIG. 3 illustrates the 3D view 301 of coupled square proof-masses in Lamé mode, with a top-down view 303. Additionally, the coupled square proof-masses are illustrated in out-of-phase breathing mode using a 3D view 305 and a top-down view 307.

Lamé mode is a type of bulk acoustic wave mode where the proof-masses vibrate in a lateral antisymmetric mode, with opposite sides expanding and contracting. The corners of the proof-masses often act as nodes during this vibration. Lamé mode can have a high Q-factor (a measure of energy dissipation) due to the low thermoelastic dissipation (TED) and high temperature turnover points, which makes Lamé mode suitable for timing applications. Lamé mode can be excited and sensed using capacitive transduction, which can offer better frequency-Q characteristics. Breathing mode is a type of oscillation where structure expands and contracts, mimicking the motion of breathing. Breathing mode can be used for sensing and driving applications. Breathing modes can also provide larger signals, feature a symmetrical design, have low energy loss, and a larger sensing signal than other modes.

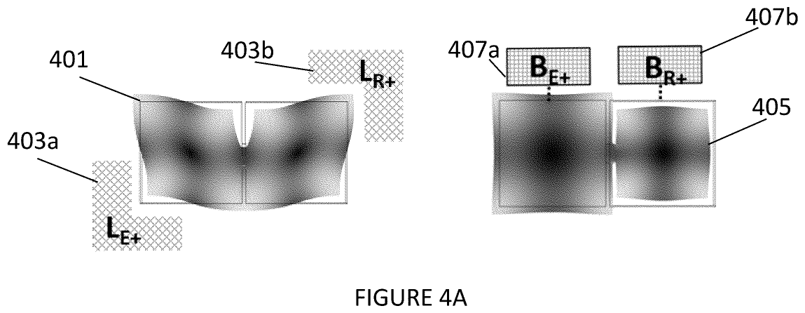

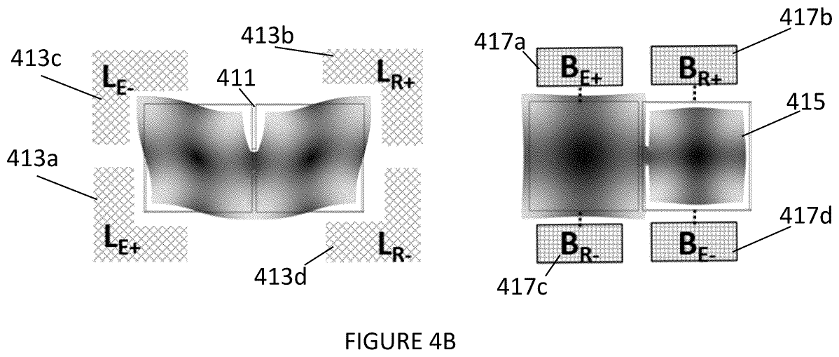

FIGS. 4A and 4B illustrate modal interaction for a dual-mode resonator assembly using single-ended excitation and differential excitation. Referring to FIG. 4A, in one embodiment, the Lamé mode single-ended electrodes 403a, 403b can be disposed at opposite corners of the coupled proof-masses 401. The electrode 403a can be an excitation electrode and the electrode 403b can be a readout electrode, or vice-versa. Similarly, in an out-of-phase breathing mode single-ended electrodes 407a and 407b can be disposed around a coupled proof-masses 405. Particularly, the single-ended electrodes 407a, 407b can be disposed on one side of the coupled masses 405. The electrode 407a can be an excitation electrode and the electrode 407b can be a readout electrode, or vice-versa.

Referring to FIG. 4B, the dual-mode resonator assembly can be configured for differential excitation. Particularly, the Lamé mode differential electrodes 413a, 413b, 413c, 413d can be disposed at each corner of the coupled proof-masses 411. The electrodes 413a, 413c can be excitation electrodes, illustrated with different notations indicating current flow, i.e., positive or negative. Additionally, the electrodes 413b, 413d can be readout electrodes, again illustrated with different current flow notations. Similarly, in an out-of-phase breathing mode differential electrodes 417a, 417b, 417c, 417d can be disposed around a coupled proof-masses 415. Particularly, the differential excitation electrodes 417a, 417c can be disposed diagonally opposite to each other. Similarly, the readout electrodes 417b, 417c can be disposed diagonally opposite to each other.

One skilled in the art would understand that FIGS. 4A and 4B illustrate one possible layout of the dual-mode resonator assembly. It should be noted that the electrode configurations as shown herein are just examples to illustrate the conceptual design. For instance, the electrodes can be disposed in different layers of substrate, positioned around the proof-masses differently, etc. Similar electrode configurations can be derived based upon the concepts and techniques as described herein. Additionally, while the electrodes as described herein are for the case of electrostatic transduction of resonators, other transduction methods (e.g., piezoelectric, thermal, piezoresistive, electromagnetic, etc.) can also be used. The geometries described in the following embodiments are designed for very small MEMS resonators with frequencies in tens of megahertz and higher. The same concepts can be used for lower frequencies by increasing the size of the resonators. In that such a design, decoupling structures both in the inner and outer periphery of the resonator may be used to improve reliability.

For the single-ended electrodes, during breathing mode, information related to Lamé mode does not get transduced. Conversely, during Lamé mode, information related to breathing mode dies is still transduced. By using differential electrodes, during breathing mode, information related to Lamé mode does not get transduced. Similarly, during Lamé mode, information related to breathing mode does not get transduced. As such, by combining the two methods, one can minimize mode interaction and/or interference between two modes used by a single resonator.

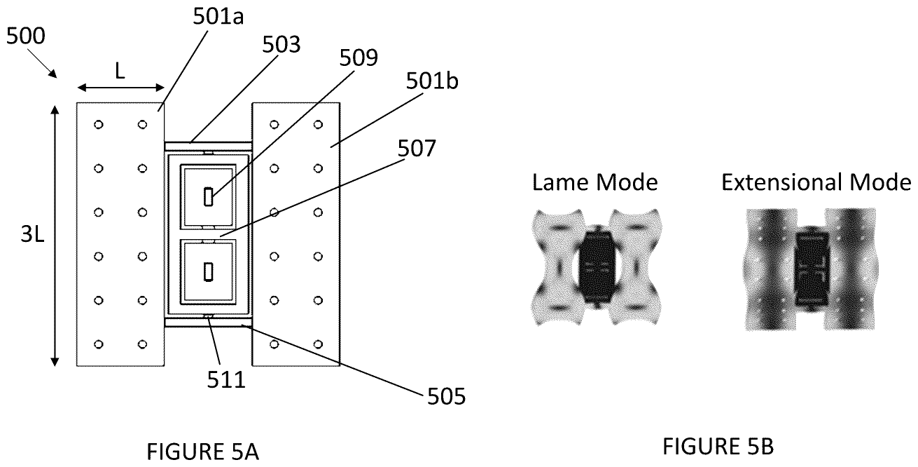

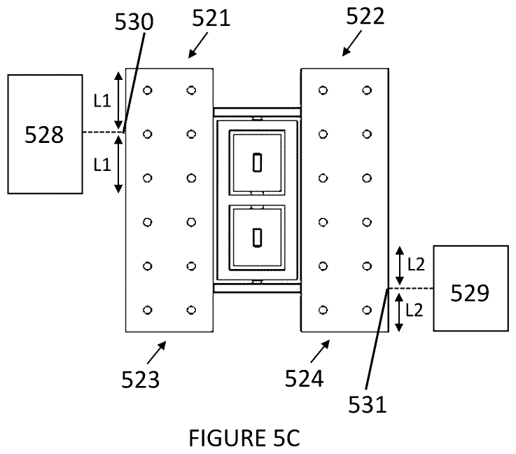

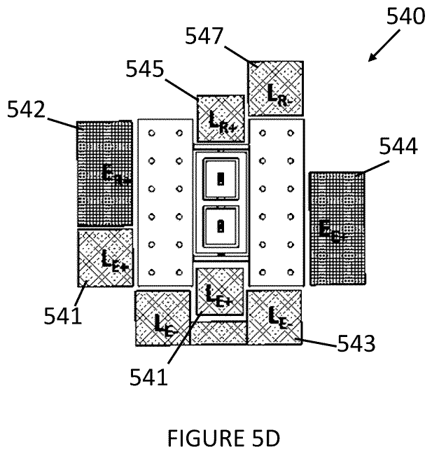

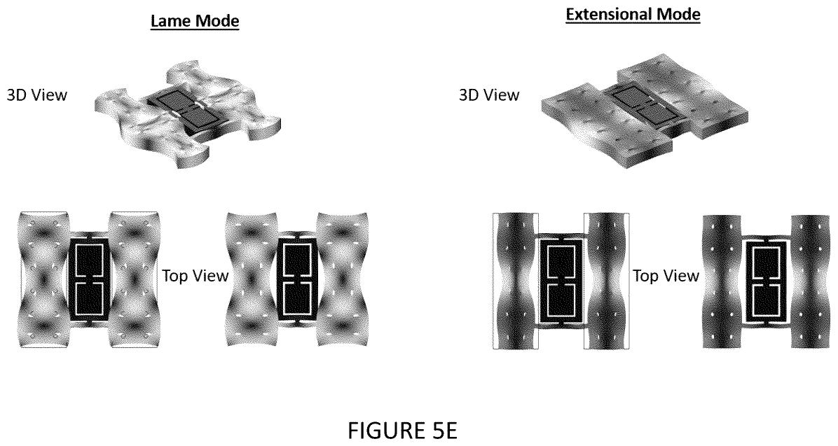

FIGS. 5A-5E illustrate a first exemplary embodiment of a dual-mode resonator assembly. As shown in FIG. 5A, the embodiment of a dual-mode resonator assembly 500 can include two plates 501a, 501b having a size 3L by L such that each plate is three squares. However, three squares are provided by way of example and the two plates 501a, 501b can include other odd numbered squares (e.g., 5, 7, etc.). The dimension of each plate determines the frequency of the Lamé and extensional modes. Extensional mode can be a symmetrical mode of vibration where the proof-mass stretches and compresses in the direction of wave propagation. Extensional modes can be used in vibration harvesting methods.

The plates 501a and 501b are proof-masses coupled together by beams 503, 505, 507. Particularly, beams 503, 505, 507 are in series and connect in-phase antinodes of plates 501a, 501b together. For both Lamé mode and extensional mode, beams 503 and 505 vibrate in response to the vibrations of plates 501a, 501b. During extension mode, beam 507 also vibrates in response to the vibrations of plates 501a, 501b. During Lamé mode the deformations of the two plates 501a, 501b cancel each other out in the middle of the beams 503, 505 (nodal point 511). Similarly, during extension mode, the deformations of the plates 501a, 501b also cancel each other out in the middle of beam 507. These deformations of both the Lamé mode and the extensional mode are shown in FIG. 5B. Because the beams 503, 505, 507 are in series, the beams significantly reduce energy loss to the anchors 509, and mitigate support-loss.

Referring to FIG. 5C, Lamé mode electrodes can be positioned on sides 521, 522, 523, 524 and configured to excite and sense the Lamé mode, but not the breathing mode. Electrodes 528, 529 can excite and sense the extensional mode, but not the Lamé mode. Electrodes 528, 529 can be the same size or different sizes. Additionally, the electrodes 528 and 529 are centered around nodes 530, 531 of the Lamé mode. That is, for example, the electrode 528 has an equal length L1 on each side of the node 530, and the electrode 529 has an equal length L2 on each side of node 531.

FIG. 5D illustrates one embodiment of electrode configuration for dual-mode operation. Particularly, the dual-mode resonator assembly 540 includes Lamé mode differential excitation electrodes 541, 543 disposed near sides 523, 524 and Lamé mode differential readout electrodes 545, 547 disposed near side 522. Extensional mode single-ended readout electrode 542 and extensional mode single-ended excitation electrode 544 are positioned similarly to electrodes 528, 529 of FIG. 5C. The extensional electrodes are centered around Lamé mode nodes.

By strategically positioning the electrodes, as shown in FIG. 5D, interference between the modes can be minimized. Additionally, the above-described electrode arrangement provides integrated multiple proof-masses to obtain a desired mode shape. Further, one skilled in the art would understand that the details of the decoupling structure and anchor can be modified to further improve support loss for dual-mode operation.

FIG. 5E illustrates sample displacement diagrams showing movement of the individual resonators in the first embodiment design. The Lamé mode and the extensional mode of the dual-mode resonator assembly 540 are shown in a 3D view and a top view. The 3D view and the top view are shown as a grey scaled heat map, where black indicates zero displacement, white indicates maximum displacement, and shades of grey indicate more or less displacement accordingly.

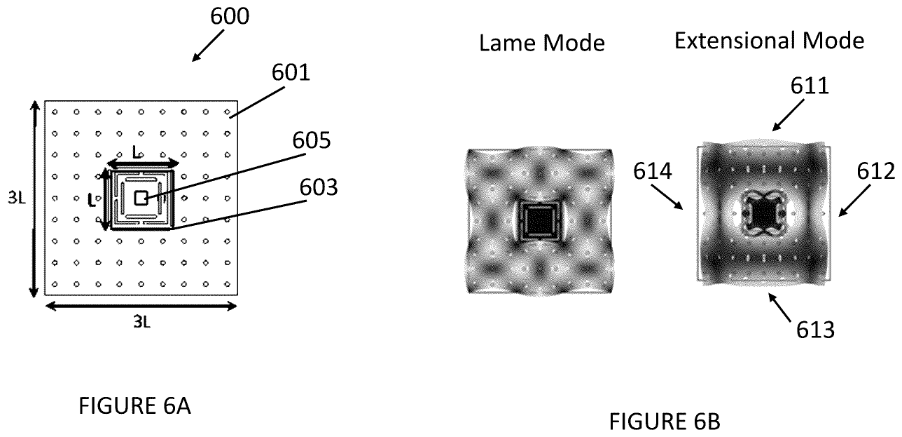

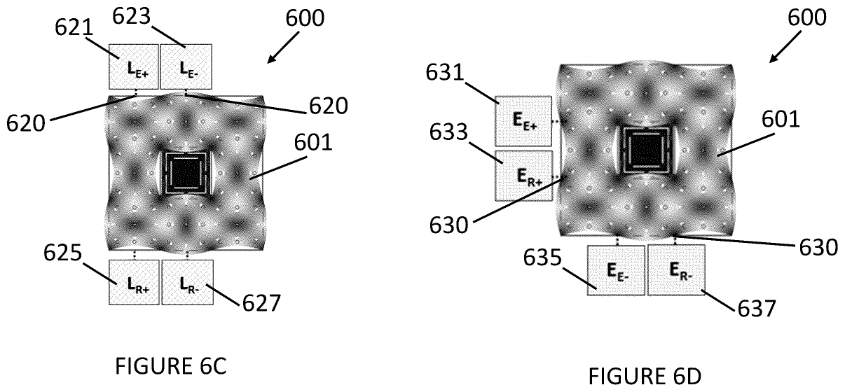

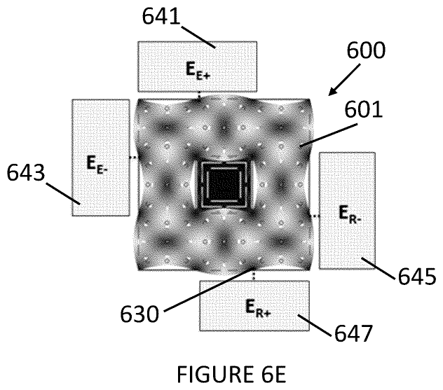

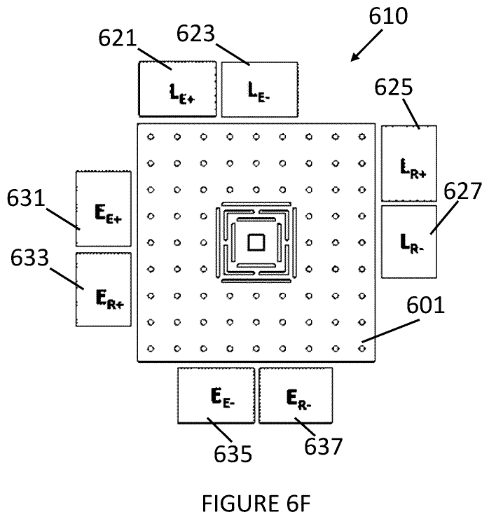

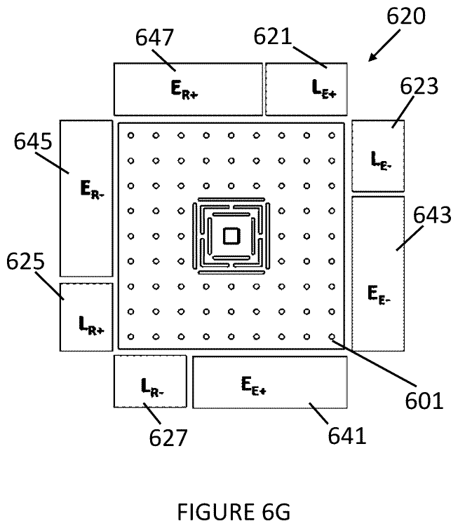

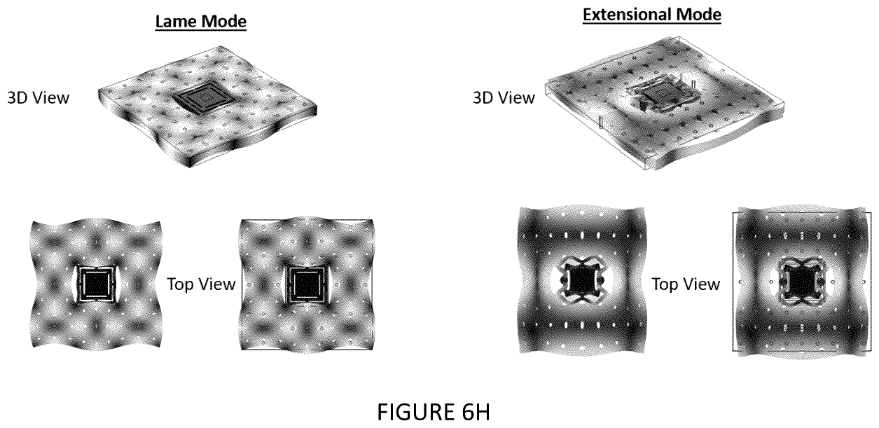

FIGS. 6A-6H illustrate a second exemplary embodiment for a dual-mode resonator assembly. As shown in FIG. 6A, the embodiment of the dual-mode resonator assembly 600 includes a single plate 601 with a length of 3L and a width of 3L. With that said, the length can be different, for example, based on various other odd integers (e.g., 5L, 7L, etc.). The dual-mode resonator assembly 600 has a square removed from the center of the plate 601, allowing structures to be connected to an interior side of the plate 601. For instance, the removed portion of the plate 601 can have a length of L and a width of L. These lengths can also be different, correspond to the length and width of the plate 601, or be independent from the dimensions of the plate 601. The dimension of the plate, and the removed portion of the plate, can determine the frequency of the Lamé and extensional modes.

The dual-mode resonator assembly 600 also can include a decoupling structure 603 that connects the inner side of the plate 601 to a central anchor 605. That is, the dual-mode resonator assembly 600 can connect the proof-mass plate 601 to the anchor without any beams. This arrangement can be optimized to reduce support loss. Additionally, because the anchor position of a resonator can directly impact the resonator's performance, having the anchor 605 central helps reduce the resonator's sensitivity to the boundary conditions and connected substrate, and therefore, mitigating support-loss. Additionally, this embodiment of the dual-mode resonator assembly can be configured to use the four corner nodes of the interior side of the plate 601 to be used to anchor the device during the Lamé mode. In other embodiments, other locations can also be used to anchor the device.

In certain implementations, the dual-mode resonator assembly 600 can have at least two resonance modes: a Lamé mode and an extensional mode. The geometry of the dual-mode resonator assembly 600 provides an extensional mode with out-of-phase sides suitable of differential excitation and readout. That is, as illustrated in FIG. 6B, sides 611 and 613 are out-of-phase with respect to sides 612 and 614, which provide a suitable position for differential excitation and readout electrodes.

Due to the single plate nature of this embodiment of the dual-mode resonator assembly, there can be a plurality of different positions for the Lamé mode and extensional mode electrodes to help mitigate modal interaction. Similar to the previous embodiment, electrode location for each mode can be selected to only excite and sense one mode and not the another. For example, FIG. 6C illustrates Lamé mode differential excitation electrodes 621, 623 and Lamé mode readout electrodes 625, 627 can be disposed in locations that have in-phase extensional mode displacement, negating any impact on extensional mode. Additionally, electrodes 621, 623, 625, 627 can be placed around antinodes 620 of the Lamé mode.

In this embodiment, the extensional mode electrodes can be configured to be centered around nodes 630 of the Lamé mode. If the extensional mode electrodes are disposed symmetrically around the nodes 630 of the Lamé mode, they can only excite and sense the extensional mode. For example, two possible configurations of the extensional mode electrodes are illustrated in FIGS. 6D and 6E. Referring to FIG. 6D, the extensional mode excitation electrodes 631, 635 and extensional mode read-out electrodes 633, 637 are symmetrically placed regarding the single plate 601. Similarly, referring to FIG. 6E, the extensional mode excitation electrodes 641, 643 and extensional mode read-out electrodes 645, 647 are symmetrically placed regarding the single plate 601.

Considering the above, by strategically positioning the electrodes, as shown in FIGS. 6C-6E, interference between the modes can be minimized. For instance, as illustrated in FIG. 6F, a dual-mode resonator assembly 610 can include Lamé mode differential excitation electrodes 621, 623, Lamé mode readout electrodes 625, 627, extensional mode excitation electrodes 631, 635, and extensional mode read-out electrodes 633, 637. Here, the Lamé mode differential excitation electrodes 621, 623 and Lamé mode readout electrodes 625, 627 can be disposed in locations that have in-phase extensional mode displacement. Additionally, the extensional mode excitation electrodes 631, 635 and extensional mode read-out electrodes 633, 637 are symmetrically placed regarding the single plate 601, while also disposed around the Lamé mode electrodes 621, 623, 625, 627.

In a different embodiment, as illustrated in FIG. 6G a dual-mode resonator assembly 620 can include Lamé mode differential excitation electrodes 621, 623, Lamé mode readout electrodes 625, 627, extensional mode excitation electrodes 641, 643, and extensional mode read-out electrodes 645, 647. Here, the Lamé mode differential excitation electrodes 621, 623 and Lamé mode readout electrodes 625, 627 can be disposed in locations that have in-phase extensional mode displacement and symmetrically to the single plate 601. Additionally, the extensional mode excitation electrodes 641, 643 and extensional mode read-out electrodes 645, 647 are symmetrically placed regarding the single plate 601, while also disposed around the Lamé mode electrodes 621, 623, 625, 627. The above arrangements of Lamé mode and extensional mode electrodes can minimize the interference between the Lamé and extensional modes.

FIG. 6H illustrates sample displacement diagrams showing movement of the resonator in the embodiment design of FIG. 6G. The Lamé mode and the extensional mode of the dual-mode resonator assembly 620 are shown in a 3D view and a top view. The 3D view and the top view are shown as a grey scaled heat map, where black indicates zero displacement, white indicates maximum displacement, and shades of grey indicating more or less displacement accordingly.

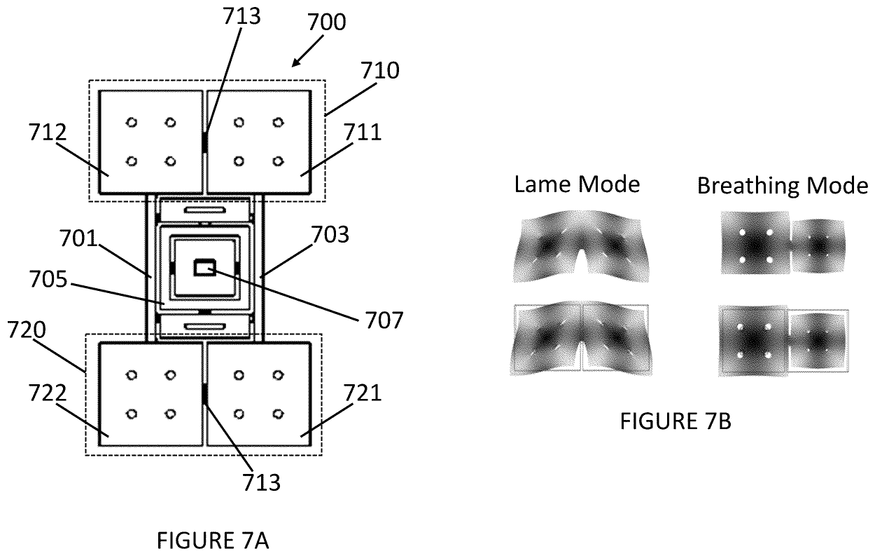

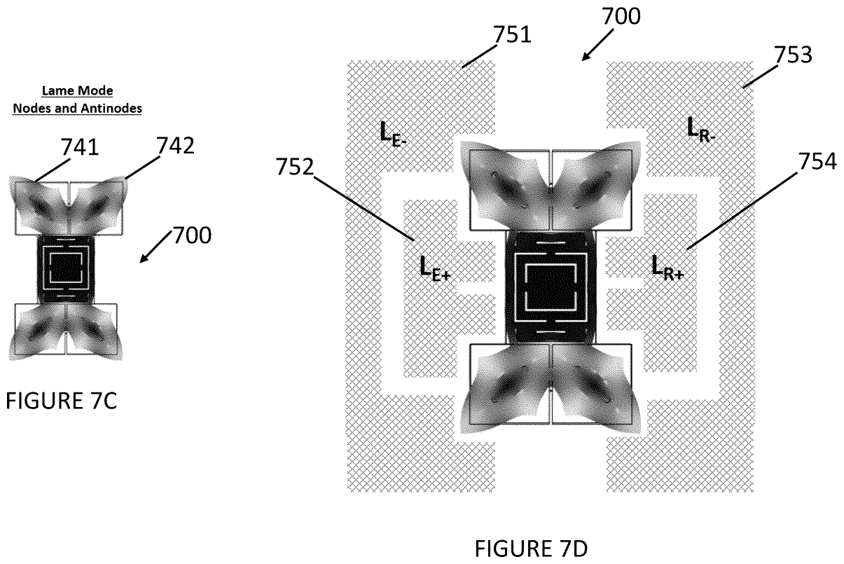

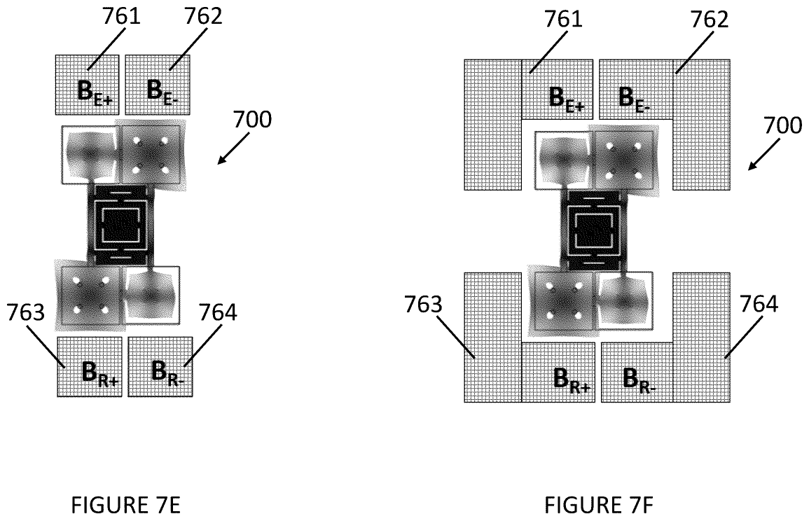

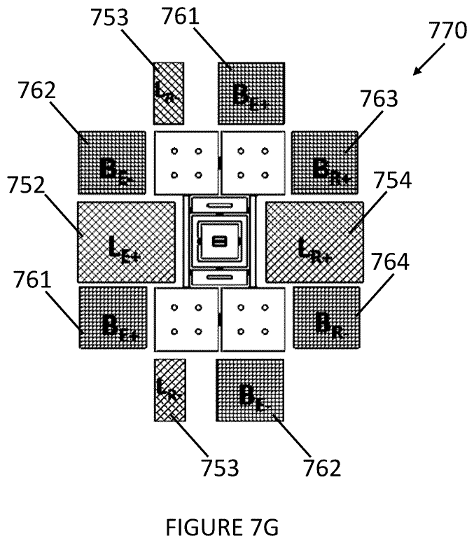

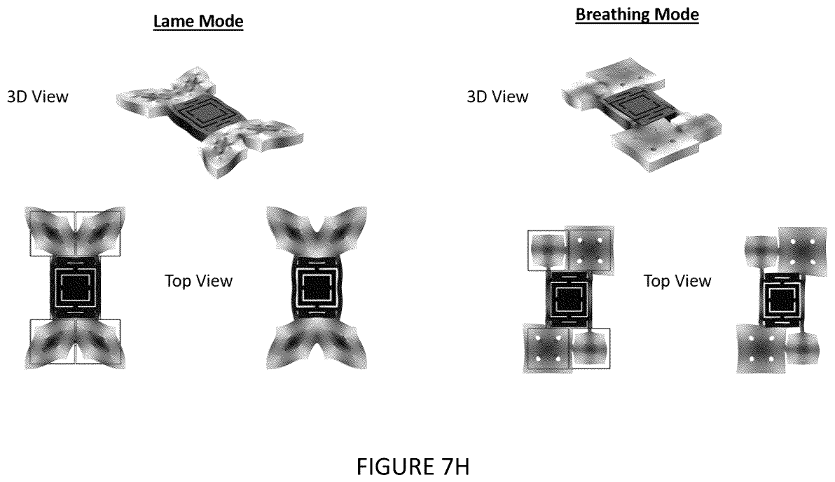

FIGS. 7A-7H illustrate a third exemplary embodiment for a dual-mode resonator assembly. In particular, a dual-mode resonator assembly can use a plurality of sets of adjacent square proof-masses connected together. For example, referring to FIG. 7A, dual-mode resonator assembly 700 can include a first set 710 of adjacent square proof-masses and a second set 720 of adjacent square proof-masses connected to an anchor 707. That is, a first set 710 of adjacent square proof-masses can include square proof masses 711, 712 connected together through a short beam 713. A second set 720 of adjacent square proof-masses can include square proof masses 721, 722 connected together through a short beam 723. The first set 710 of adjacent square proof-masses and second set 720 of adjacent square proof-masses can be connected together using a plurality of long beams. Here, the first set 710 and the second set 720 are connected together by long beam 701 and 703. In other embodiments, a single long beam or more than two long beams connect the first set 710 and the second set 720.

The long beams 701, 703 can connect the first set 710 and the second set 720 to an anchor 707 via a decoupling structure 705. The anchor 707 and decoupling structure 705 can be centrally disposed between the first set 710 of adjacent square proof-masses and the second set 720 of adjacent square proof-masses. In other embodiments, the anchor 707 can be offset and/or off centered, i.e., closer to one set than the other set, or asymmetrical of the two sets of adjacent square proof-masses. Additionally, in some embodiments, a plurality of anchors is disposed centrally, or symmetrically with respect to the two sets. In other embodiments, more than two sets of adjacent square proof-masses are connected to an anchor or plurality of anchors.

Dual-mode resonator assembly 700 can have at least two resonance modes: a Lamé mode and a breathing mode, as illustrated in FIG. 7B. In Lamé mode, the first set 710 can vibrate in a first phase, and the second set 720 can vibrate in a second phase. That is, the two adjacent square proof-masses 711, 712 can vibrate in-phase, and the two adjacent square proof-masses 721, 722 can also vibrate in-phase. In this manner, the Lamé mode can include of the two sets 710, 720 vibrating in-phase, with four total square proof-masses are vibrating. The dual-mode resonator assembly 700 can be configured to have the two adjacent square proof-masses of each set connected to each other through nodes of Lamé mode. In other embodiments, the first set and the second set can vibrate out of phase with each other.

In the breathing mode of the dual-mode resonator assembly 700, the two adjacent proof-masses are configured to be barely coupled when vibrating in their respective breathing mode. That is, when in breathing mode, the adjacent square proof-masses 711, 712 are barely connected. As a result of this lack of coupling, the adjacent square proof-masses will vibrate out-of-phase with each other.

Similar to the embodiments described above, the dual-mode resonator assembly 700 can include a decoupling structure 705 that connects inner side of the resonator body to the central anchor 707. In some embodiments, the decoupling structure can connect the long beams 701, 703 to a central anchor 707. Having a central anchor helps reduce the dual-mode resonator assembly performance sensitivity to boundary conditions of the anchor and the connected substrate. Additionally, the decoupling structure 705 can be optimized to reduce support loss.

Referring to FIG. 7C, naturally the dual-mode resonator assembly 700 has nodes 741 and antinodes 742. In this embodiment of the dual-mode resonator assembly 700, there can be a plurality of different positions for the Lamé mode and breathing mode electrodes to help mitigate modal interaction. For example, the Lamé mode electrodes can be preferably centered around the antinodes 742 of the Lamé mode. Differential excitation and/or readout for Lamé mode can be disposed in locations that have in-phase breathing mode displacement, which helps negate the impact on breathing mode. For example, referring the FIG. 7D, the Lamé mode excitation electrodes 751, 752 can be disposed around the displacement of the antinodes 742 of Lamé mode. Similarly, the Lamé mode readout electrodes 753, 754 can be disposed around the displacement of the antinodes of Lamé mode. Here, FIG. 7D illustrates the electrodes 751, 752, 753, 754 as differential nodes, i.e., the readout/excitation electrodes having a plurality of nodes. However, in other embodiments, only a single readout or excitation electrode can be used. The Lamé mode electrodes 751, 752, 753, 754 can be symmetrical to the dual-mode resonator assembly 700, as illustrated in FIG. 7D. In other embodiments, the Lamé mode electrodes can be asymmetrical.

The dual-mode resonator assembly 700 can have breathing mode electrodes centered around nodes of the Lamé mode. For example, as illustrated in FIGS. 7E and 7F, breathing mode excitation electrodes 761, 762 and breathing mode readout nodes 763, 764 are disposed around the nodes 741 of the Lamé mode of the resonator 700. The electrodes 761, 762, 763, 764 can be symmetrically disposed around the nodes 741 of the Lamé mode, and configured to only excite and sense the breathing mode.

Considering the above, by strategically positioning the electrodes, as shown in FIGS. 7D-7F, interference between the modes can be minimized. For instance, as illustrated in FIG. 7G, a dual-mode resonator assembly 770 can include Lamé mode excitation electrode 752, Lamé mode readout electrodes 753, 754, breathing mode excitation electrodes 761, 762, and breathing mode read-out electrodes 763, 764. This embodiment does not use a differential excitation method, but rather can use a single Lamé mode excitation electrode 752. In other embodiments, the dual-mode resonator assembly 770 can use a differential excitation method including a plurality of excitation electrodes.

FIG. 7H illustrates sample displacement diagrams showing movement of the resonators of the embodiment illustrated in FIG. 7G. The Lamé mode and the breathing mode of the dual-mode resonator assembly 770 are shown in a 3D view and a top view. The 3D view and the top view are shown as a grey scaled heat map, where black indicates zero displacement, white indicates maximum displacement, and shades of grey indicating more or less displacement accordingly.

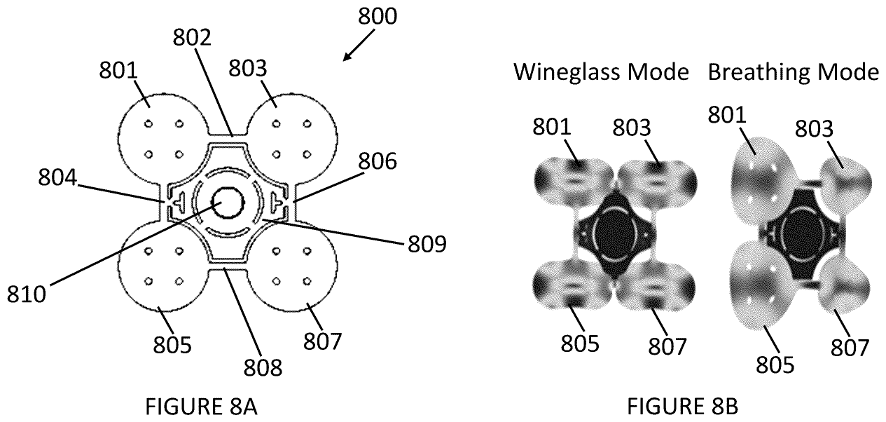

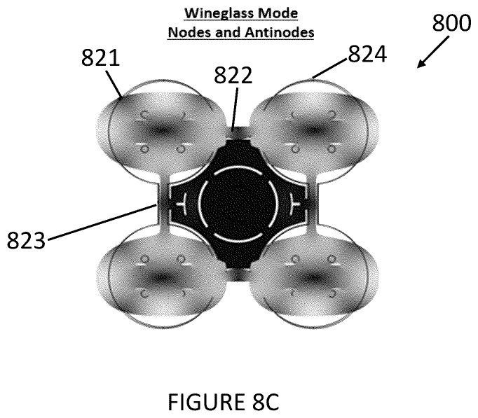

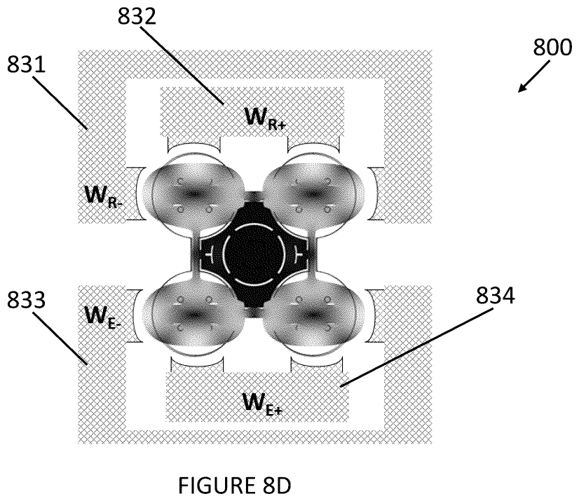

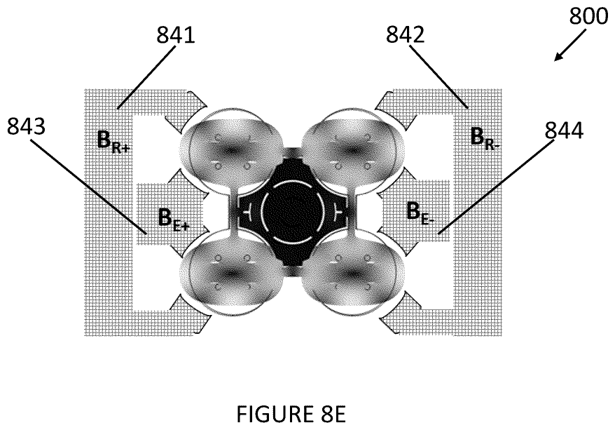

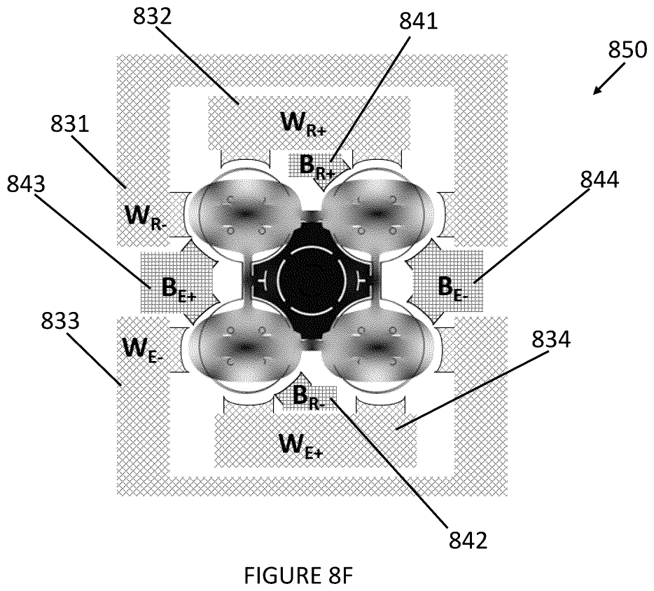

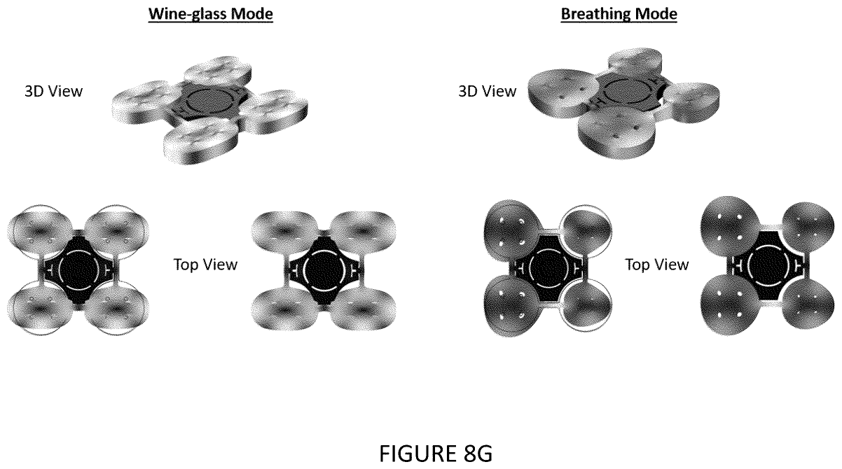

FIGS. 8A-8G illustrate a fourth exemplary embodiment for a dual-mode resonator assembly. In particular, a dual-mode resonator assembly can use a plurality of disk proof-masses connected via four beams. For example, referring to FIG. 8A, dual-mode resonator assembly 800 can include a four disk proof-masses 801, 803, 805, 807 connected to each other using four beams 802, 804, 806, 808. Specifically, the disk proof-masses are positioned such that each disk is connected to two other disks, e.g., disk proof-mass 801 is connected to disk proof-masses 803 and 805 via long beams 802 and 804, respectively. The middle of the beams 804 and 806 can connected to a central anchor 810 through a decoupling structure 809. In other embodiments, all the long beams are connected to the decoupling structure 809 or only a single long beam can be connected to the decoupling structure 809.

Dual-mode resonator assembly 800 can have at least two resonance modes: a wineglass mode and a breathing mode, as illustrated in FIG. 8B. A wineglass mode can vibrate in a unique pattern resembling the shape of a wineglass when excited at its resonant frequency. Typically, a wineglass mode is characterized by lateral displacements that are in anti-phase between the x-axis and y-axis. Typically, a wineglass mode is used in disk shaped, ring shaped, and shell shaped resonators.

Here, in wineglass mode, all four disk proof-masses 801, 803, 805, 807 vibrate in-phase, and all four beams 802, 804, 806, 808 vibrate in their extensional mode and have a node at the center of the beam. In breathing mode, two disks that are connected via a vertical beam vibrate in phase. For example, as illustrated in FIGS. 8A and 8B, disk proof-masses 801 and 805 are connected to the same vertical beam 804 and vibrate in phase, and disk proof-masses 803 and 807 are connected to the same vertical beam 806 and vibrate in phase, but both sets are out of phase with each other. As a result, the two vertical beams 804, 806 vibrate in their extensional modes with a node at the center of the beam while the two horizontal beams 802, 808 are translating during vibration. In other embodiments, the horizontally connected disk proof-masses vibrate in-phase with each other while the vertically connected disk proof-masses vibrate out of phase with each other.

Similar to the embodiments described above, the dual-mode resonator assembly 800 can include a decoupling structure 809 that connects inner side of the resonator body to the central anchor 810. Having a central anchor helps reduce the dual-mode resonator assembly performance sensitivity to boundary conditions of the anchor and the connected substrate. Additionally, the decoupling structure 809 can be optimized to reduce support loss.

Referring to FIG. 8C, naturally dual-mode resonator assembly 800 in wineglass mode has nodes 821, 822, 823 and antinodes 824. In this embodiment of the dual-mode resonator assembly 800, there can be a plurality of different positions for the wineglass mode and breathing mode electrodes to help mitigate modal interaction. Particularly, the electrode locations for each mode can be selected to only excite and sense one mode and not the other mode. For example, the wineglass mode electrodes are preferably centered around the antinodes 824 of the wineglass mode. Differential excitation and/or readout for wineglass mode can be disposed in locations that have in-phase breathing mode displacement, which helps negate the impact on the breathing mode.

For example, referring the FIG. 8D, the wineglass readout electrodes 831, 832 and the wineglass excitation electrodes 833, 834 can be disposed in locations that have in-phase breathing mode displacement. Here, FIG. 8D illustrates the electrodes 831, 832, 833, 834 as differential nodes, i.e., the readout/excitation electrodes having a plurality of nodes. However, in other embodiments, only a single readout or excitation electrode can be used. The wineglass mode electrodes 831, 832, 833, 834 can be symmetrical to the dual-mode resonator assembly 800, as illustrated in FIG. 8C. In other embodiments, the wineglass electrodes can be asymmetrical.

The dual-mode resonator assembly 800 can have breathing mode electrodes centered around nodes of the wineglass mode. For example, as illustrated in FIGS. 8E, breathing mode excitation electrodes 843, 844 and breathing mode readout nodes 841, 842 are disposed around the nodes of the wineglass mode of the resonator 800. The electrodes 841, 842, 843, 844 can be symmetrically disposed around the nodes 841 of the Lamé mode, and configured to only excite and sense the breathing mode.

Considering the above, by strategically positioning the electrodes, as shown in FIGS. 8C-8E, interference between the modes can be minimized. For instance, as illustrated in FIG. 8F, a dual-mode resonator assembly 850 can include wineglass readout electrodes 831, 832, wineglass excitation electrodes 833, 834, breathing mode excitation electrodes 843, 844 and breathing mode readout nodes 841, 842. Disposing the electrodes in this manner mitigates modal interaction and prevents electrodes from exciting and sensing more than one mode.

FIG. 8G illustrates sample displacement diagrams showing movement of the resonators of the embodiment illustrated in FIG. 8F. The wineglass mode and the breathing mode of the dual-mode resonator assembly 850 are shown in a 3D view and a top view. The 3D view and the top view are shown as a grey scaled heat map, where black indicates zero displacement, white indicates maximum displacement, and shades of grey indicating more or less displacement accordingly.

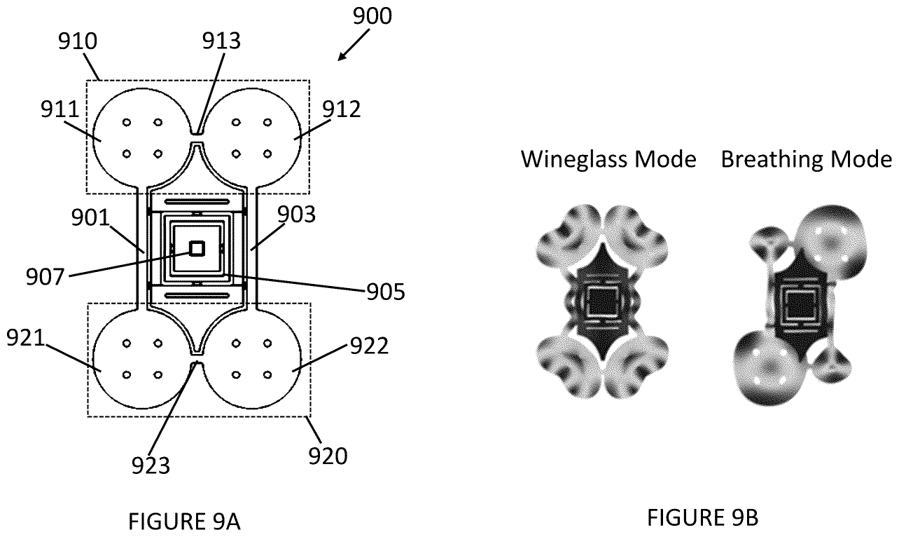

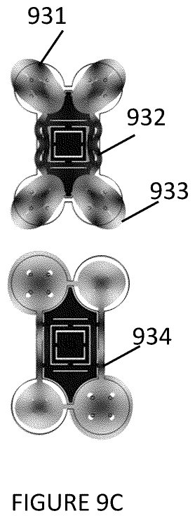

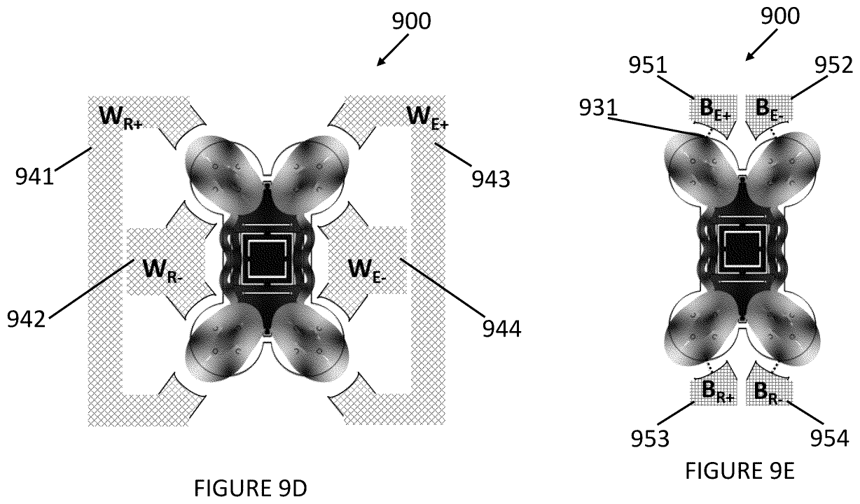

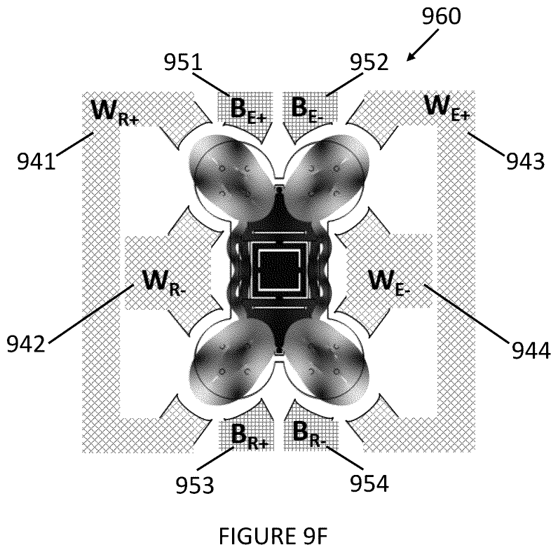

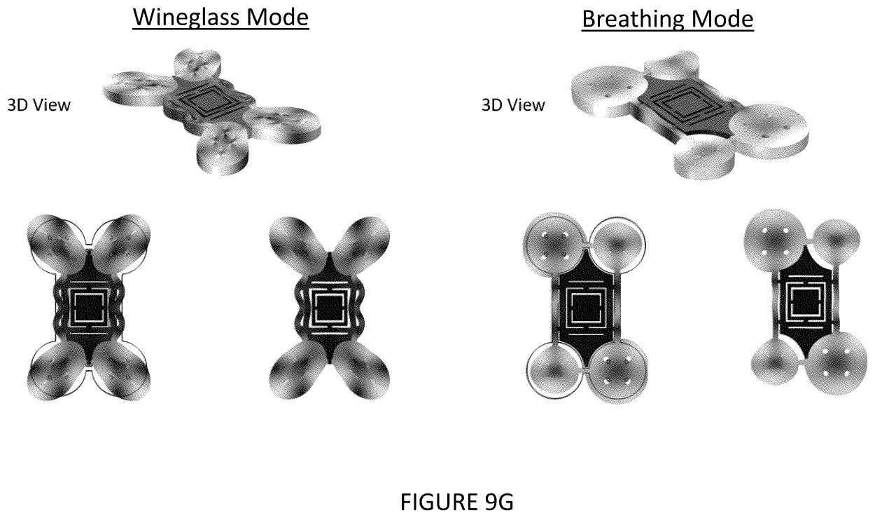

FIGS. 9A-9G illustrate a fifth exemplary embodiment for a dual-mode resonator assembly. In particular, a dual-mode resonator assembly can use a plurality of sets of adjacent disk proof-masses connected together. For example, referring to FIG. 9A, dual-mode resonator assembly 900 can include a first set 910 and a second set 920 of adjacent disk proof-masses connected to an anchor 907. That is, a first set 910 of adjacent disk proof-masses can include disk proof-masses 911, 912 connected together through a short beam 913. A second set 920 adjacent disk proof-masses can include disk proof masses 921, 922 connected together through a short beam 923. The first set 910 of adjacent disk proof-masses and second set 920 of adjacent disk proof-masses can be connected together using a plurality of long beams. Here, the first set 910 of adjacent disk proof-masses and the second set 920 of adjacent disk proof-masses are connected together by long beam 901 and 903.

In other embodiments, a single long beam or more than two long beams connect the first set 910 of adjacent disk proof-masses and the second set 920 of adjacent disk proof-masses. The long beams 901, 903 can connect the first set 910 of adjacent disk proof-masses and the second set 920 of adjacent disk proof-masses to an anchor 907 via a decoupling structure 905. The anchor 907 and decoupling structure 905 can be centrally disposed between the first set 910 of adjacent disk proof-masses and the second set 920 of adjacent disk proof-masses. In other embodiments, the anchor 907 can be offset and/or off centered, i.e., closer to one set than the other set, or asymmetrical of the two sets of adjacent square proof-masses. Additionally, in some embodiments, a plurality of anchors is disposed centrally, or symmetrically with respect to the two sets. In other embodiments, more than two sets of adjacent square proof-masses are connected to an anchor or plurality of anchors.

Similar to the embodiments described above, the dual-mode resonator assembly 900 can include a decoupling structure 905 that connects the long beams 901, 903 to the central anchor 907. Having a central anchor 907 helps reduce the dual-mode resonator assembly performance sensitivity to boundary conditions of the anchor and the connected substrate. Additionally, the decoupling structure 905 can be optimized to reduce support loss.

Dual-mode resonator assembly 900 can have at least two resonance modes: a wineglass mode and a breathing mode, as illustrated in FIG. 9B. In wineglass mode, all four disk proof-masses 911, 912, 921, 922 vibrate in-phase, and the two long beams 901, 903 vibrate in their flexural mode and have multiple nodes. Flexural mode is characterized by significant out-of-plane displacement, contrasting with the in-plane motion of extensional modes.

In breathing mode, the two adjacent disk proof-masses are hardly coupled when vibrating in their breathing modes, and as a result they will vibrate out-of-phase with respect to each other. Additionally, in breathing mode, the first set 910 of adjacent disk proof-masses and the second set 920 of adjacent disk proof-masses vibrate out-of-phase with respect to each other, as illustrated in FIG. 9B. As a result of the out-of-phase vibrating, the two vertical beams 901, 903 can include two nodes, each node used as a connection to the decoupling structure. In other embodiments, the horizontally connected disk proof-masses vibrate in-phase with each other while the vertically connected disk proof-masses vibrate out of phase with each other.

For example, referring to FIG. 9C, the dual-mode resonator assembly 900 has nodes 931, 932 and antinode 933 in wineglass mode. In breathing mode, the dual-mode resonator assembly 900 has nodes 934.

In this embodiment of the dual-mode resonator assembly 900, there can be a plurality of different positions for the wineglass mode and breathing mode electrodes to help mitigate modal interaction. Particularly, in a manner where the electrode locations for each mode can be selected to only excite and sense one mode and not the other mode. For example, the wineglass mode electrodes are preferably centered around the antinodes 933 of the wineglass mode. Differential excitation and/or readout for wineglass mode can be disposed in locations that have in-phase breathing mode displacement, which helps negate the impact on the breathing mode.

For example, referring the FIG. 9D, the wineglass mode readout electrodes 941, 942 and the wineglass mode excitation electrodes 943, 944 can be disposed around the displacement of the antinodes of wineglass mode. Here, FIG. 9D illustrates the electrodes 941, 942, 943, 944 as differential nodes, i.e., the readout/excitation electrodes having a plurality of nodes. However, in other embodiments, only a single readout or excitation electrode can be used. The wineglass mode electrodes 941, 942, 943, 944 can be symmetrical to the dual-mode resonator assembly 900, as illustrated in FIG. 9D. In other embodiments, the Lamé mode electrodes can be asymmetrical.

The dual-mode resonator assembly 900 can have breathing mode electrodes centered around nodes of the wineglass mode. For example, as illustrated in FIGS. 9E, breathing mode excitation electrodes 951, 952 and breathing mode readout nodes 953, 954 are disposed around the nodes 931 of the wineglass mode of the resonator 900. The electrodes 951, 952, 953, 954 can be symmetrically disposed around the nodes of the wineglass mode, and configured to only excite and sense the breathing mode.

Considering the above, by strategically positioning the electrodes, as shown in FIGS. 9D-9E, interference between the modes can be minimized. For instance, as illustrated in FIG. 9F, a dual-mode resonator assembly 960 can include wineglass mode readout electrodes 941, 942, wineglass mode excitation electrodes 943, 944, breathing mode excitation electrodes 951, 952, and breathing mode readout nodes 953, 954. This embodiment accommodates both the wineglass mode and the breathing mode while reducing the impact of each mode on the other.

FIG. 9G illustrates sample displacement diagrams showing movement of the resonators of the embodiment illustrated in FIG. 9F. The Lamé mode and the breathing mode of the dual-mode resonator assembly 960 are shown in a 3D view and a top view. The 3D view and the top view are shown as a grey scaled heat map, where black indicates zero displacement, white indicates maximum displacement, and shades of grey indicating more or less displacement accordingly.

Having thus described several aspects of at least one example, it is to be appreciated that various alterations, modifications, and improvements will readily occur to those skilled in the art. For instance, examples disclosed herein can also be used in other contexts. Such alterations, modifications, and improvements are intended to be part of this disclosure and are intended to be within the scope of the examples discussed herein. Accordingly, the foregoing description and drawings are by way of example only.

Also, the phraseology and terminology used herein is for the purpose of description and should not be regarded as limiting. Any references to examples, components, elements or acts of the systems and methods herein referred to in the singular can also embrace examples including a plurality, and any references in plural to any example, component, element or act herein can also embrace examples including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “of” can be construed as inclusive so that any terms described using “or” can indicate any of a single, more than one, and all of the described terms. In addition, in the event of inconsistent usages of terms between this document and documents incorporated herein by reference, the term usage in the incorporated references is supplementary to that of this document; for irreconcilable inconsistencies, the term usage in this document controls.

What is claimed is:

1. A dual-mode resonator comprising:
a resonator assembly comprising:
a plurality of proof-masses configured to vibrate in a first mode of operation and a second mode of operation;
at least one anchor;
at least one beam; and
a decoupling structure,
the plurality of proof-masses being coupled to the at least one anchor by the at least one beam and the decoupling structure; and
a plurality of electrodes disposed around the periphery of the resonator assembly and configured to transduce information related to the first mode of operation and the second mode of operation, the plurality of electrodes comprising:
at least two sets of first electrodes configured to operate the first mode of operation, and
at least two sets of second electrodes configured to operate the second mode of operation,
wherein operation of the dual-mode resonator in the first mode of operation results in minimal vibration or movement at a plurality of first nodes and maximum vibration or movement at a plurality of first antinodes, and
wherein operation of the dual-mode resonator in the second mode of operation results in minimum vibration at a plurality of second nodes and maximum vibration or movement at a plurality of second antinodes.

2. The dual-mode resonator of claim 1, wherein the first mode of operation is a low temperature coefficient of frequency (TCF) mode configured to create a reference clock signal and the second mode of operation is a high TCF mode configured to sense temperature and perform temperature compensation.

3. The dual-mode resonator of claim 1, wherein the at least two sets of first electrodes are configured to only operate the first mode of operation, and
wherein the at least two sets of second electrodes are configured to only operate the second mode of operation.

4. The dual-mode resonator of claim 1, wherein the at least two sets of first electrodes are disposed symmetrically around the plurality of first nodes.

5. The dual-mode resonator of claim 1, wherein the at least two sets of second electrodes are disposed symmetrically around the plurality of first nodes.

6. The dual-mode resonator of claim 1, wherein the at least two sets of first electrodes and the at least two sets of second electrodes are disposed symmetrically around the plurality of first nodes.

7. The dual-mode resonator of claim 1, wherein the at least two sets of first electrodes are disposed symmetrically around the plurality of first antinodes.

8. The dual-mode resonator of claim 1, wherein the at least two sets of second electrodes are disposed symmetrically around the plurality of first antinodes.

9. The dual-mode resonator of claim 1, wherein the at least two sets of first electrodes and the at least two sets of second electrodes are disposed symmetrically around the plurality of first antinodes.

10. The dual-mode resonator of claim 1, wherein at least two proof-masses of the plurality of proof-masses are coupled together by at least two beams.

11. The dual-mode resonator of claim 1,
wherein at least two sets of proof-masses of the plurality of proof-masses are coupled together by at least two beams,
wherein each set of proof-masses comprise two proof-masses connected together by a single beam.

12. The dual-mode resonator of claim 1, wherein at least four proof-masses of the plurality of proof-masses are coupled together by at least four beams.

13. The dual-mode resonator of claim 1, wherein the first mode of operation is a Lamé mode.

14. The dual-mode resonator of claim 1, wherein the first mode of operation is a wineglass mode.

15. The dual-mode resonator of claim 1, wherein the second mode of operation is an extensional mode.

16. The dual-mode resonator of claim 1, wherein the second mode of operation is a breathing mode.

17. The dual-mode resonator of claim 1, wherein the at least two sets of first electrodes comprise two sets of first differential electrodes, and the at least two sets of second electrodes comprise two sets of second differential electrodes.

18. The dual-mode resonator of claim 1, wherein the at least two sets of first electrodes comprise at least one set of electrodes that is not a differential electrode set.
